(19) United States
(12) Patent Application Publication
(10) Pub. No.: US 2012/0279069 A1
(43) Pub. Date: Nov. 8, 2012

(54) METHODS AND EQUIPMENT FOR CONSTRUCTING SOLAR SITES

(76) Inventor: David L. Von Deylen, Napoleon, OH (US)

(21) Appl. No.: 13/486,458

(22) Filed: Jun. 1, 2012

Related U.S. Application Data
(63) Continuation-in-part of application No. 13/262,966, now abandoned.
(60) Provisional application No. 61/212,212, filed on Apr. 8, 2009.

(51) Int. Cl. H01L 31/18

(52) U.S. Cl. 29/890.033; 29/700

(57) ABSTRACT

A method of constructing a solar harvesting site includes positioning support risers for supporting numerous solar panel cartridges before any solar panel cartridges are mounted. Preferably, risers for the entire site are positioned consecutively in a continuous process. Solar panel cartridges, preferably with pre-mounted and pre-wired solar panels, are then mounted on the risers consecutively in a continuous process. Unique equipment to automate the method includes an anchor vehicle to position risers in a continuous manner and a carrier to automatically position cartridges onto the risers in a continuous manner.

### REFERENCE TO RELATED APPLICATIONS

This application claims priority from and is a continuation-in-part of U.S. application Ser. No. 13/262,966, filed Oct. 5, 2011, which is national stage application of PCT Application Serial No. PCT/US2010/030399, filed Apr. 8, 2010, which claims priority form U.S. Provisional Application Ser. No. 61/212,212, filed Apr. 8, 2009, the disclosures of which are hereby incorporated by reference.

### FIELD OF THE INVENTION

The invention generally relates to solar panels, and more particularly to methods and equipment for installing solar panels in large scale solar energy collection fields.

### BACKGROUND

Solar panels harvest solar energy and convert it to electricity. Solar panels systems are widely used on both roof top and ground surface applications. Most solar panels are silicone based and heavy and must be adequately supported. Solar panel support systems, therefore, are typically formed from heavy gauge steel. It is common for panel support devices to include numerous parts such as frames, mounting sleeves, elevation pivots, rails, etc. The parts of solar panel support systems are typically welded, ground, coped, sanded and plated prior to assembly. Solar panel support systems are expensive to transport and handle due to their weight.

Large utility scale solar energy harvesting fields are increasingly desirable. However, the cost of installing solar panel systems can be high, as installers currently use inefficient and labor intensive solar panel support system designs and construction methods. Some prior solar panel support designs provide support for only one or two panels on a pole. Other large utility scale solar energy harvesting fields are more efficient because the solar panels are arranged more densely. Such fields utilize compact rows of abutting solar panels, some of which may be supported by common support posts or risers. While the compact panel layout allows more efficient use of an area, prior support system designs and construction methods remain labor intensive and inefficient.

A typical solar panel cartridge 10 is shown in FIG. 1. As used herein, the term “cartridge” means a frame on which one, or more typically, more than one solar panel is mounted. Cartridge 10 is made of steel frame members 12. Several solar panels 16 are mounted on cartridge 10. The panels 16 are wired together so that the panels 16 mounted in the cartridge 10 can be electrically connected to other panels and the electrical grid. The cartridge 10 is supported by risers 14 which are anchored in the ground, on a rooftop, etc. Solar panel cartridge 10 has a typical rectangular configuration, but other shapes are feasible as well. Cartridge 10 is mounted on risers 14 at the corners where frame members 12 connect, but supporting cartridges at points intermediate the corners is common as well.

Typically, solar panel cartridges are fabricated on-site, with solar panels individually mounted onto the cartridge and wired together. At the site, risers for supporting each cartridge are anchored in position in the ground, on a rooftop, etc., and the solar panel and cartridge assembly is then mounted thereon. Finally, all panels at the site are electrically connected to each other and to the power grid. The assembly of individual cartridges and solar panels, one-at-a-time, is often difficult and time consuming at the on-site location. Electrical wiring of each individual solar panel is also difficult and time consuming. Weather conditions often hamper the on-site assembly process. A better and more efficient system is needed.

It would be advantageous to provide more efficient construction methods as well as improved solar panel support assembly designs that can streamline construction and assembly. Such designs must be sufficient to support the solar panel cartridges and be convenient to handle and assemble. It would be further advantageous if such designs included built-in features that would accommodate automated construction of utility scale solar power harvesting fields.

### SUMMARY OF THE INVENTION

The present invention is an efficient method of constructing a large-scale solar harvesting site having numerous solar panels. In the method, solar panel support risers for supporting at least two solar panel cartridges are positioned before the first solar panel cartridge is mounted. Preferably, risers for the entire site are positioned consecutively in a continuous process. Solar panel cartridges, preferably with pre-mounted and pre-wired solar panels, are then mounted on the risers consecutively in a continuous process.

Unique equipment may be used to automate the method. An anchor vehicle may be used to position risers at proper spacing and height, and in a continuous manner. A carrier vehicle may also be used to automatically handle and position cartridges onto the risers in a continuous manner. Such vehicles may use sensors and programmable controllers for automating the process.

### BRIEF DESCRIPTION OF THE DRAWINGS

FIG. 1 is a perspective view of a prior art solar cartridge.

FIGS. 2a-f illustrate a first series of schematic perspective views of a solar field being constructed according to the present invention.

FIGS. 3a-e illustrate a second series of schematic perspective views of a solar field being constructed according to an alternative aspect of the present invention.

FIG. 4a is a rear perspective view of an anchor positioning attachment of the present invention.

FIG. 4b is a front perspective view of the anchor positioning attachment of FIG. 4a.

FIG. 5 is a perspective view of a carrier vehicle of the present invention.

FIG. 6 is perspective view of a solar panel support of the present invention.

FIG. 7 is an exploded perspective view of a frame support assembly of the present invention.

FIG. 8 is a cross-sectional view of a portion of the frame support assembly taken along line 8-8 of FIG. 7.

FIG. 9 is an exploded perspective view of a solar panel support of the present invention.

FIG. 10a is an exploded perspective view of a portion of the solar panel support of FIG. 9.

FIG. 10b is a perspective view of the cap of FIG. 10a.

FIG. 10c is a perspective view of the cap of FIG. 10a positioned on a riser.

### DETAILED DESCRIPTION OF PREFERRED EMBODIMENTS

The present invention is suitable for constructing large scale solar harvesting sites which may have hundreds of solar panel cartridges. The present invention includes methods for constructing solar panel cartridges for delivery to solar harvesting sites, methods for automated construction of solar panel harvesting sites, equipment for automated solar panel site construction, as well as solar panel cartridge designs suitable for efficient construction.

### Prepanelization Method

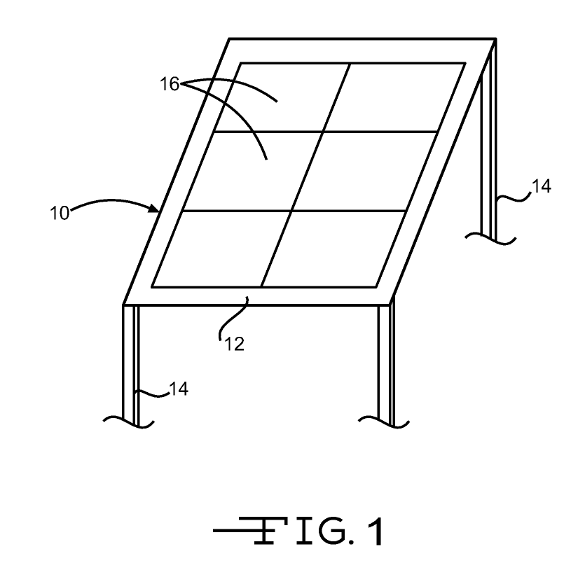

The present invention includes a process for preparing solar panel cartridges for delivery to solar panel harvesting sites. The method includes assembling a solar panel cartridge such as 10 of FIG. 1 by securing together frame members 12 by any suitable method, such as welding, riveting, mechanical staking, bolting, screwing, gluing, etc. The cartridge may be of any shape, but rectangular is preferred. Frame members generally define the periphery of the cartridge, but panel support members intermediate the peripheral frame members are typical for cartridges that include multiple solar panels.

Next, solar panels are mounted in the cartridge. If crystalline panels with aluminum frames are used, the panels are then grounded to the cartridge frame members. Thin film panels do not require grounding. Next, the panels in the cartridge are wired together and the wires are secured to the cartridge frame members with clips or otherwise to prevent exposure to the elements after the solar panels are positioned at the harvest site. Optionally, the panel wiring can be done on-site if the solar field is small. Finally, the solar panel cartridges are palletized in a protected in a secure manner for shipment to a solar panel harvest site.

### Construction and Assembly Method

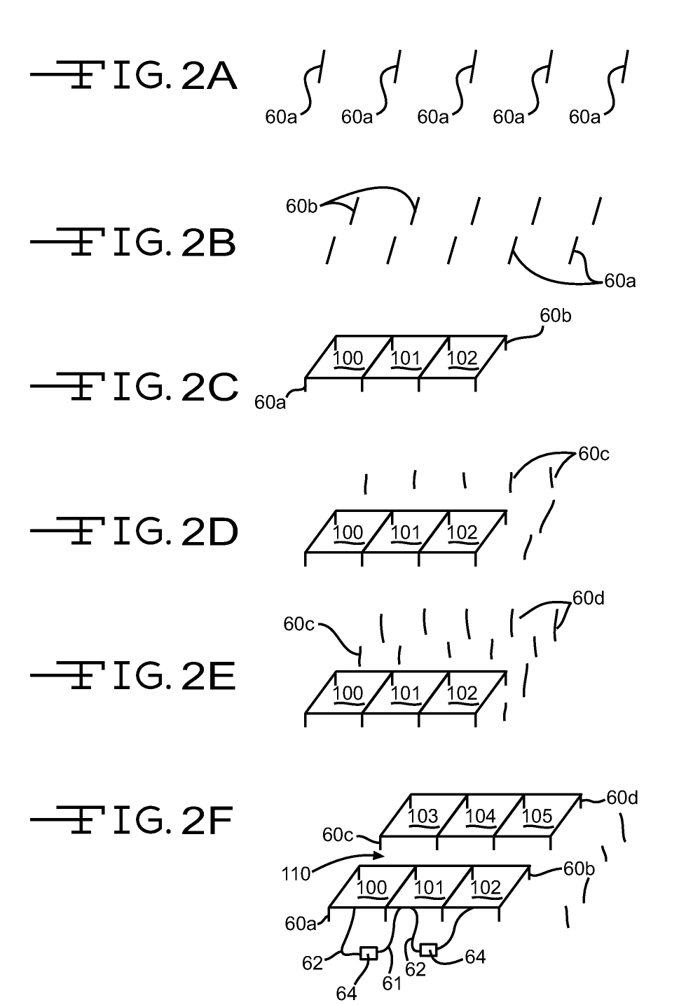

Referring to FIG. 2a, the method of constructing a large solar panel harvesting site includes an initial step of positioning a series or array of risers 60a in the ground, on a rooftop, etc. The risers 60a may be positioned manually or with automated equipment, such as the equipment that will be described herein.

Preferably, the risers 60a are positioned individually, in sequence, with next adjacent risers positioned one after the other. However, the order of positioning or placement of the array of risers 60a may vary depending on the size and shape of the solar field, the workforce used, etc. For example, in certain situations it may be appropriate to position risers at the end of each array before placing the risers intermediate of the end risers. In other situations, it may be appropriate to position the array of risers 60a in a random order. The risers 60a are in a linear array, but other configurations are possible; for example, a curved array of risers is possible, even for rectangular panels, if the panels are not abutting or are supported by only one common riser. Depending upon the size of the solar field, there may be hundreds or more risers 60a in the array.

Referring to FIG. 2b, the next step in the process is to position a second series of risers 60b in an array parallel to first positioned array of risers 60a. Generally, it is preferred that the risers form a series of rectangles to accept rectangular solar panel cartridges to be mounted either at the cartridge frame corners or at intermediate points on the cartridge frames. Of course, while a rectangular pattern is most common, other configurations are possible; for example, a staggered riser pattern may be preferred when the cartridges are to be mounted at points intermediate the cartridge frame corners.

As with the first series of risers 60a, the order of placement of each riser 60b is preferably sequential, with next adjacent risers positioned one after the other. However, again as with the first series of risers 60a, random or other orders of placement may be appropriate in certain situations. All risers may be of any height to provide a desired pitch for maximum solar panel sun exposure.

When an adequate number of risers are positioned, solar panel cartridges can be mounted. In certain situations, it may be appropriate to position all risers of a solar field before assembling any solar panel cartridges onto the risers. However, depending on other factors, such as the size of the solar field, the workforce available, etc., it may be feasible to begin assembly of the solar panel cartridges onto the risers before all risers are positioned. For example, in large solar fields, it may be feasible for a workforce to begin mounting and connecting the solar panel cartridges while a separate workforce is simultaneously completing the placement of risers.

Referring to FIG. 2c, rectangular solar panel cartridges 100, 101, 102 are mounted onto the risers 60a and 60b, forming a first row of solar panel cartridges, each supported at its corners by four risers. Next adjacent panels, such as 100/101 and 101/102, have two common risers to create an array of abutting cartridges for maximum efficiency. Of course, different solar panel cartridge shapes and support arrangements may be used. For example, risers may be positioned to support solar panel cartridge frames at locations other than the corners. In addition, solar panels cartridges may be mounted without common risers for better support or to provide an access space between next adjacent cartridges.

Next, referring to FIG. 2d, to create a second row of solar panel cartridges, preferably parallel to the first row for maximum ground cover efficiency, a third row of risers 60c is positioned in a manner similar to that of risers 60a and 60b. Next, referring to FIG. 2e, a fourth row of risers 60d is positioned in a similar manner. Each of the rows of risers 60c and 60d are in a linear array and are parallel to the linear arrays of risers 60a and 60b.

Referring to FIG. 2f, solar panel cartridges 103, 104, 105, etc. are then positioned on risers 60c and 60d, with the risers attached to the cartridge frame corners and abutting pairs of cartridges 103/104 and 104/105 being supported by common risers. The rows of cartridges are not supported by common risers, thereby creating an aisle 110 between the rows for access and maintenance purposes. However, if the aisle 110 is not necessary, such as in a roof mounted site in which the panels are arranged in a single plane (i.e a flat arrangement in which panels are not tilted relative to each other), risers in adjacent rows, for example 60b and 60c, could be used to support three or four cartridges, similar to the manner in which adjacent cartridges 100 and 101 are supported.

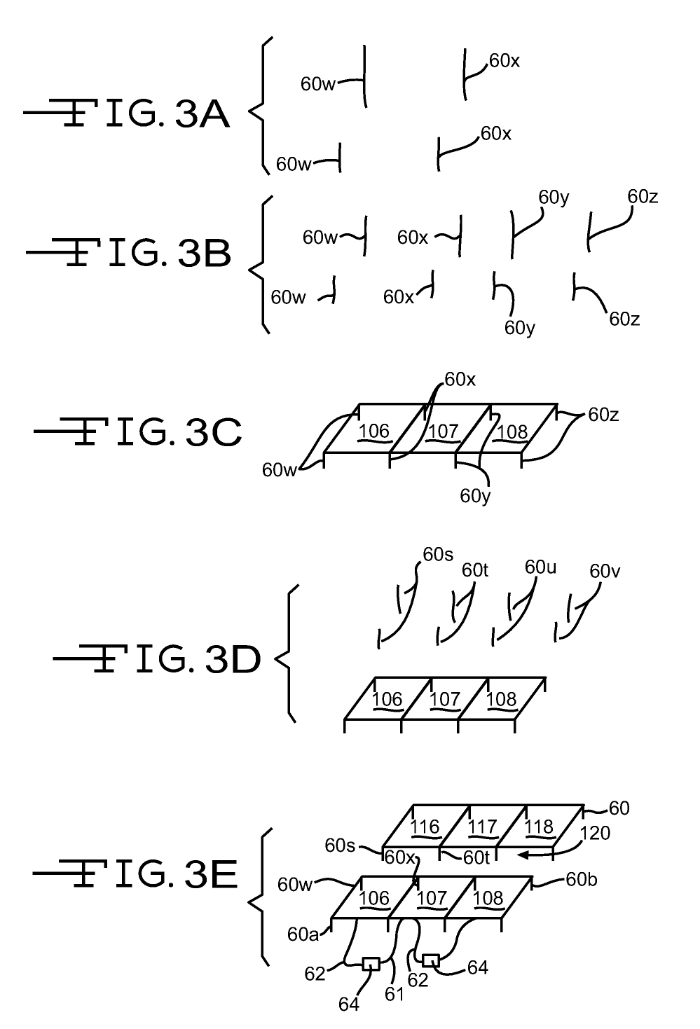

Referring to FIGS. 3a-e, an alternative method of constructing a solar panel field includes an initial step of positioning two risers 60w and a second step of positioning two risers 60x, all for supporting a first rectangular solar panel cartridge. The risers 60w, 60x may be positioned manually or with automated equipment which facilitates positioning of risers two-at-a-time as will be described herein.

Next, referring to FIG. 3b, an additional two risers 60y are positioned adjacent the risers 60x, followed by two more risers 60z, thereby creating two parallel rows of risers similar to the rows of risers 60a, 60b of FIG. 2b. The process of positioning additional risers along the linear arrays is continued for the entire width or length of the solar field, which may include hundreds or more risers and solar panels.

Referring to FIG. 3c, after the riser groups 60w, 60x and 60y are positioned, rectangular solar panel cartridges 106, 107, 108 are assembled onto the risers. Common risers 60x support both cartridges 106 and 107 which abut each other. Similarly, common risers 60y support both cartridges 107 and 108. Alternatively, risers 60w and 60x may support a single cartridge and risers 60y and 60z may support another cartridge, leaving an access space therebetween. As with the embodiment of FIGS. 2a-f, different solar panel cartridge shapes and support arrangements may be used. For example, risers may be positioned to support solar panel cartridge frames at locations other than the corners.

Additional rows of solar panel cartridges may be created similarly. As shown in FIG. 3d, pairs of risers 60s, 60t, 60u, 60v are positioned, preferably in sequence, similar to the positioning of riser pairs, 60w, 60x, 60y, 60z. Referring to FIG. 3e, solar panel cartridges 116, 117, 118 are then assembled onto the risers. The rows of cartridges are not supported by common risers, thereby creating an aisle 120 between the rows for access and maintenance purposes. However, as with the first embodiment, if aisle 120 is unnecessary such as in a roof mounted site in which the panels are arranged in a single plane and are not tilted relative to each other, risers in adjacent rows, such as 60x and 60t, could support four cartridges, similar to the manner in which adjacent cartridges 106 and 107 are supported.

The present invention contemplates that risers for an entire solar field may be positioned prior to mounting any solar panel cartridges. This method allows for a positioning of risers in a continuous manner without stopping to install cartridges. However, the present invention also contemplates that that similar efficiencies may be gained in large solar fields when a work force separate from that which installs the risers is used to install the cartridges on the risers; in such case, cartridges may be installed onto risers as soon as a sufficient number of risers are positioned. Automated equipment for applying the method will be described herein.

The present invention includes off-site assembly and wiring of the solar panels and cartridge assemblies, including pre-wiring of the panels of each cartridge. Off-site assembly can be done in a more efficient factory setting under optimum conditions, as opposed to on-site assembly with inefficiencies which may be caused by weather, access, and other factors.

When at least two solar panel cartridges are mounted on risers, electrical connections may be made. Referring to FIGS. 2f and 3e, a single electrical input line 61 and a single electrical output line 62 are required for each cartridge. The input and output lines are electrically connected at a junction 64. This can be done simply with one connection for each cartridge to a home run string and ultimately to the electrical grid as is well known in the art. If not done in a prepanalization step, the wiring can then be secured within the frame members of each cartridge. On-site electrical wiring is reduced to a minimum.

### Construction and Assembly Vehicles

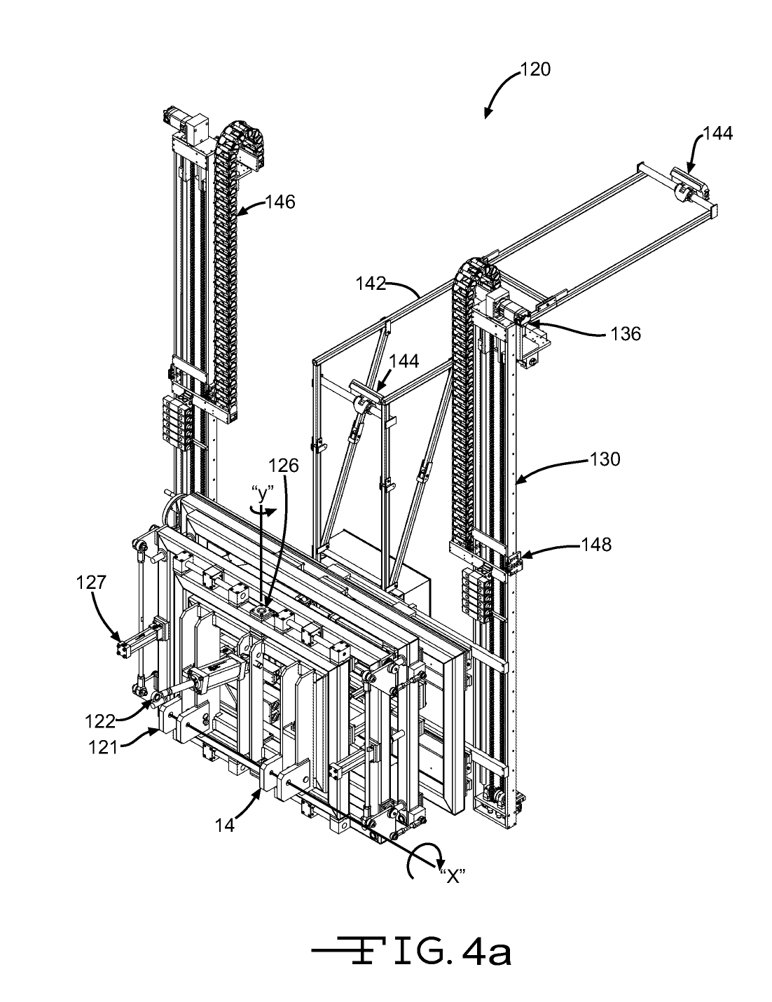

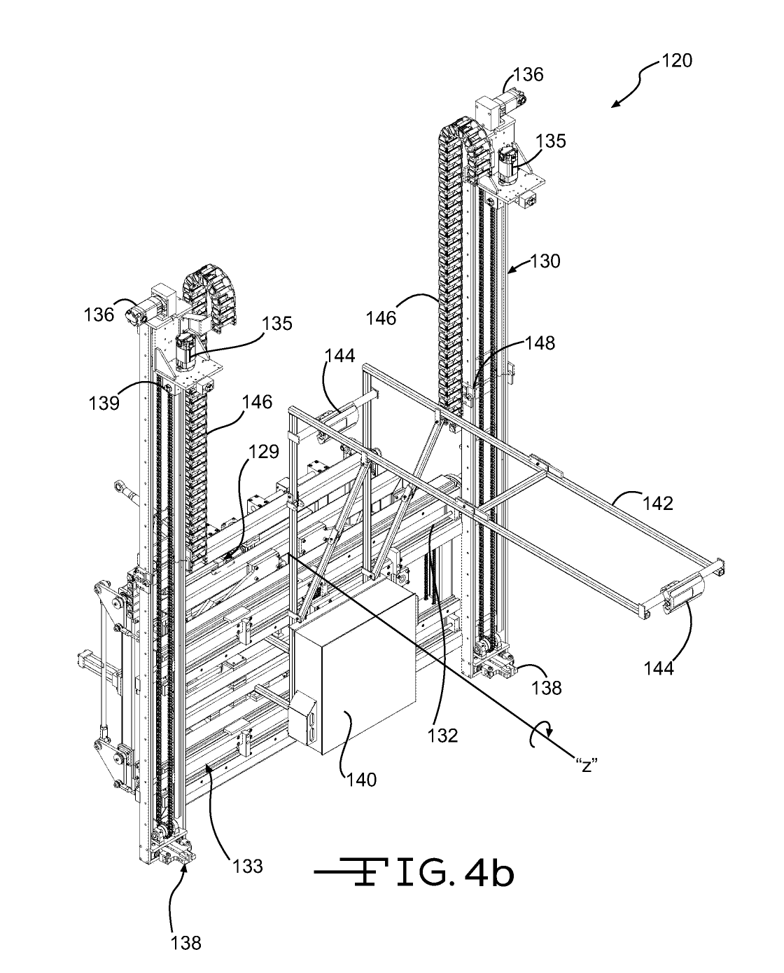

The present invention includes the automated installation of solar panels in a large area solar field. Referring to FIGS. 4a and 4b, a solar panel riser anchoring assembly 120 is adapted to be secured to a tractor (not shown) with fasteners attached to a three point hitch commonly found on the rear of typical farm tractors. The tractor's hydraulic system is used to drive the hydraulic components of the assembly 120. The assembly 120 includes frame members 121 which provide two attachment points to the tractor. A third attachment point from the assembly frame to the tractor is provided through a cylinder 122 which can orient the assembly 120 around the “x” axis through attachment points 121.

Vertical pivot 126 allows the assembly 120 to rotate about a vertical “y” axis. Hydraulic cylinder 127 provides the force to rotate the assembly 120 around the vertical axis. Hydraulic cylinder 129 provides the force to rotate the assembly 120 around a “z” axis. It therefore will be apparent that the assembly 120 can be oriented in a desired position regardless of the orientation of the tractor on which it is mounted.

The assembly 120 includes a control box which includes, among other controls, programmable logic controller and a gyroscope (not shown) for orienting the assembly 120. It is generally preferred that anchor risers are positioned in a “plumb” orientation, i.e. aligned with the center of the earth, regardless of the local terrain into which the risers are placed. The gyroscope provides information to allow the controller which communicates with a processor which instructs the automated devices to properly position the assembly 120 and the masts 130 for insertion of risers.

The assembly 120 includes anchor riser positioning masts 130 and complimentary screw 132 and guide 133 for adjusting the centerline of the masts. The space between the masts 130 is therefore adjustable to provide flexibility with respect to differently sized solar panel cartridges. Each mast 130 includes a riser rotating motor for turning risers as they are inserted in the ground. Each mast also includes a drive motor 136 for driving anchor risers vertically downwardly into the ground as the risers are being turned. Each mast 130 includes a guide 138 at its lower end to hold the anchor risers in place as they are being inserted into the ground. Anchor risers are positioned in each mast manually. The two masts 130 facilitate the simultaneous positioning of parallel rows of risers, but a vehicle with a single mast may be used to position a single row of risers. Each mast 130 includes a dimpling tool 139 for creating dimples at the top of an anchor riser, as will be explained herein.

The assembly includes a laser frame 142 on which are mounted laser receivers 144. The laser receivers 144 assure that the risers are vertically positioned. The assembly 120 also includes protective wire and hose trays 146 attached to each mast 130 in which are placed the various electrical wires and hydraulic hoses of the system. Finally, the assembly 120 includes mast hinges 148 to allow the masts 130 to fold down for transportation or storage purposes.

While the spacing of risers between the masts 130 is important, the spacing of the risers in a row of risers is less critical and is preferably accomplished using a GPS. Alternatively, a cable or tape measure can be used to position each riser in a row, with the position of each measured from an initially placer riser to eliminate any stack-up error.

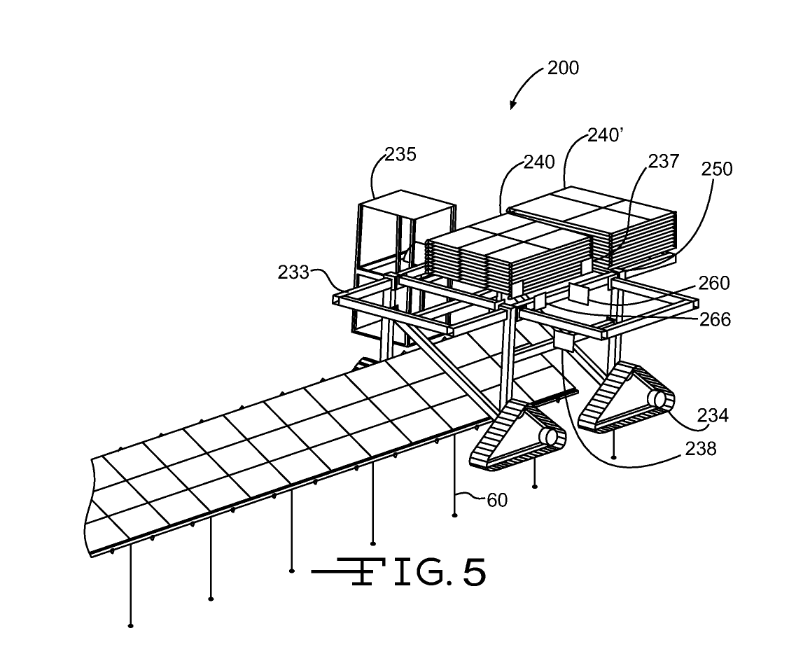

Referring to FIG. 5, a self-propelled solar paver or carrier 200 carries stacks of solar panel cartridges 240, 240′ (with or without solar panels installed). The carrier 200 includes an integrated hydraulic drive and pump system for operating robotic arms and other on-board hydraulic and/or electronic automated devices. These devices move the solar panel cartridges from a staged, in-queue, position on the carrier to positions for installation on risers as shown.

The carrier includes a steel frame with a centrally located lift 237. A cartridge transfer system includes a first gripper 266 having fingers for holding the stack of cartridges as a single cartridge is separated and lowered from the stack. A linear device 250 operably connects to the carrier's hydraulic system to adjust the height of the stack of cartridges after each cartridge is removed. A second gripper 238 moves individual cartridges into position above risers which have been positioned on the site. A side shift device 260 sets the pitch of the cartridge lowered onto the risers. Optional tooling (not shown) may be used to position caps on the risers as will be described herein. The fingers of the gripper 266 are then retracted, and the anchoring, the transferring, and the securing steps are repeated until all solar panels in the area are installed.

When the last cartridge in a stack 240 has been positioned, a second in-queue stack 240′ is moved laterally toward the central portion of the cartridge. The simultaneous movement of the stacks and the incremental movement of the vehicles 120, 200 insure that the assembly operation is continuous.

The carrier 200 is driven by the system's hydraulics through tracks 234 which stabilize the vehicle. A climate controlled elevated cab 235 provides operator comfort and clear observation of system operations. The carrier includes lights for night operation. The carrier may be equipped with mechanisms and controls which serve the same function as the anchor vehicle alignment locator 140 so that the accuracy in anchoring the risers 60 may be repeated with respect to the lowering of the panels onto the tops of the risers.

The anchor vehicle 120 and/or carrier 200 may be guided by laser points predetermined at the installation site or via GPS. Either or both anchor vehicle and carrier may be powered by gasoline, diesel fuel, electronic fuel panels or other known means and may include a hydraulic pump or generator, which may provide motive power as well as power for the automated means and transfer assemblies.

### Solar Panel Support

The present invention includes a universal solar panel support which provides manufacturing, shipping, and installation efficiencies. The support is useful for both ground and rooftop applications. The support includes a cartridge onto which solar panels may be interchangeably installed and replaced. Cartridges may be installed manually or by way of the automated installation method described above.

Referring to FIG. 6, a flat roof system has cartridges 20 which include a top frame member 22, a bottom frame member 24, and a pair of opposite side members 26, 28. Each side member 26, 28 has an end portion 23, 25 that mates with a corresponding end portion 27, 29 of the top and bottom frame members 22, 24, respectively, to form interlocking releasable snap-fit joints. The cartridges 20, therefore, may be quickly and easily assembled without tools.

Cartridge support members 40 extend between the top and bottom frame members to support for the solar panels. A central support rail 34 is also provided for added strength, particularly for cartridges which hold six or more solar panels. Each cartridge may also be equipped with wire carrier holes (not shown) formed in the top, bottom, side, and/or support members, through which electrical wires may be neatly threaded for connecting the panels and panels to the appropriate grid.

Alternatively, the top, bottom, and side frame members 22, 24, 26, 28 may be connected using known means such as mechanical staking, spot welding, rivets, machine screws, etc. Other appropriate fasteners may also be used, such as pre-threaded rivet systems in which fewer fasteners are needed and site installation is less labor intensive.

Upstanding hollow risers 60 support the cartridge 20 and solar panels. The risers may be supported by several different base configurations or anchoring systems that allow the cartridge assembly to be mounted on surfaces such as the ground, a flat roof, or a pitched roof. A preferred embodiment includes two risers 60 connected to a cartridge 20 which extends between the risers. It will be readily understood by those skilled in the art that the cartridges may be interlocked to produce any size of panel support desirable.

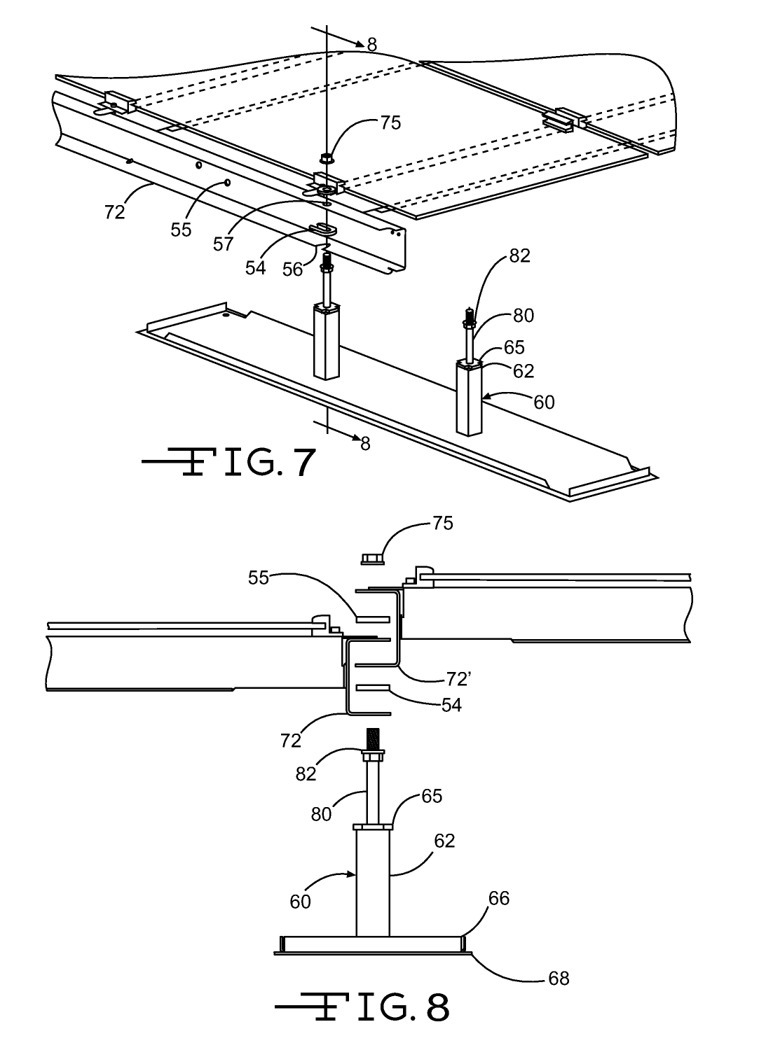

The risers 60 may be sized to produce a sloped pitched orientation of the cartridge and solar panels as desired. As shown in FIG. 6, each pair of risers 60 connected to and supported in an elongate base 64. The base includes a ballast tray 66 for containing ballast materials such as bricks, aggregate, or the like. The ballast prevents unintentional movement of the cartridge 20 in those applications where the riser is otherwise unsecured to the ground surface, such as in roof top installations, for example. Seismic padding 68 (FIG. 8) may be installed on the underside of the base 64 to prevent damage to EDPM sealed flat roofs, roof membranes, or other non-penetrable roof surfaces.

The cartridges 20 and risers 60 are formed from carbon steel and high strength low-alloy steel with a galvanized coating. However, other rigid materials may be used, such as other metals or plastic. Cartridges 20 carry Z-shaped fasteners for attaching thin film solar panels. Fasteners 50 include a resilient, generally U-shaped insert biased between a leg portion of the fastener and the cartridge. The inserts prevent damage to solar panels when installed onto the cartridges 20. The solar panels are received into U-shaped openings in the resilient inserts. The fasteners are secured at spaced locations along the length of the support members 40 during manufacture and assembly of the cartridges using means known by skilled artisans, such as welding, bolts, rivets or the like. Pre-threaded rivets lock the fasteners to the cartridges 20. Preferably, the cartridges 20 are pre-assembled prior to delivery to a solar harvesting site with or without solar panels to dramatically reduce installation time and labor at the site.

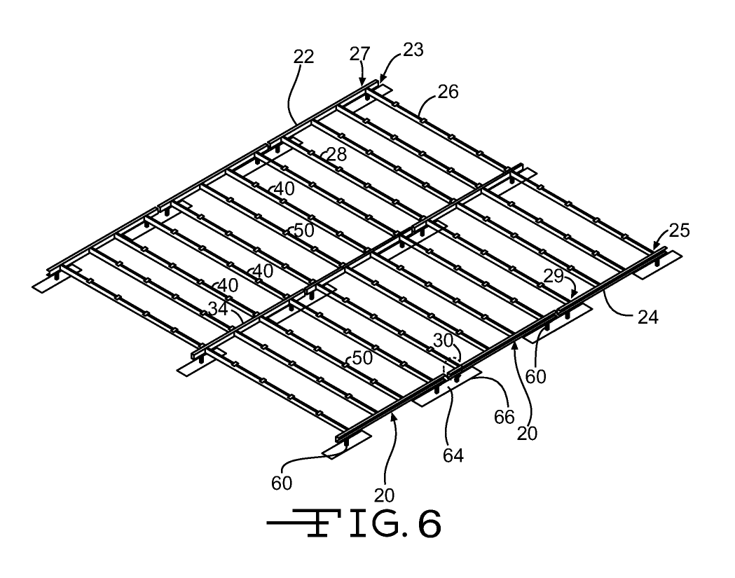

Referring to FIGS. 7 and 8, a rooftop solar panel mounting system includes risers 60, each riser 60 having a tube 62 as a standoff. A plate 65 with protruding stud 80 is attached to the top of each tube 62. A nut 82 is pre-installed onto the stud 80 providing a resting surface for the cartridge frame members 72. The cartridge frame 72 has a C-shaped cross-section with a hole 57 in the top flange and a notch 56 in the lower flange directly below the hole 57.

When the risers 60 are fixed in place, cartridge frame 72 is placed on the riser with the top flange hole 57 placed over the stud 80 and the top flange resting on the pre-installed nut 82. The lower flange notch 56 is positioned around the stud 80. A set of C-shaped spacers 54, 55 is then installed around the stud 80 on the top and bottom flanges of the installed cartridge frame 72. The adjoining cartridge 72′ is then installed by placing the top flange hole 57 over the stud 80 and allowing the lower flange notch 56 to slide around the stud 80, with the lower flange resting on the lower spacer 54 and the top flange resting on the top spacer 55. A top nut 75 is threaded onto the top of the stud 80 and tightened, compressing the entire assembly and locking eth cartridges in place.

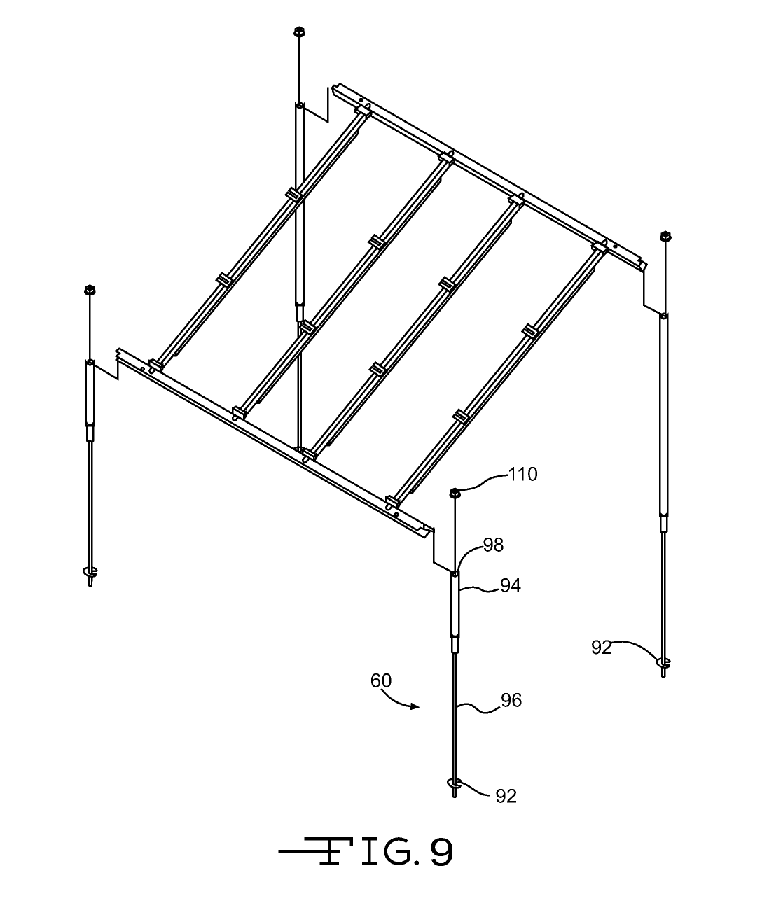

Referring to FIG. 9, a field mount solar panel system has risers 60 including a top portion 94 crimped to a lower portion 96. Risers 60 include a spade in the form of an auger 92 for penetrating and anchoring the risers in the ground. Alternatively, tapered spikes or other designs for penetrating and anchoring a riser in the ground may be used. Ground anchors are generally driven to a point well below the frost line to prevent any movement due to frost heave, and thus prevent damage to the panel table and assembly. Like the risers of the rooftop or free-standing panel support embodiments described above, the risers 60 are of predetermined lengths so that the resulting solar panel table is pitched as shown.

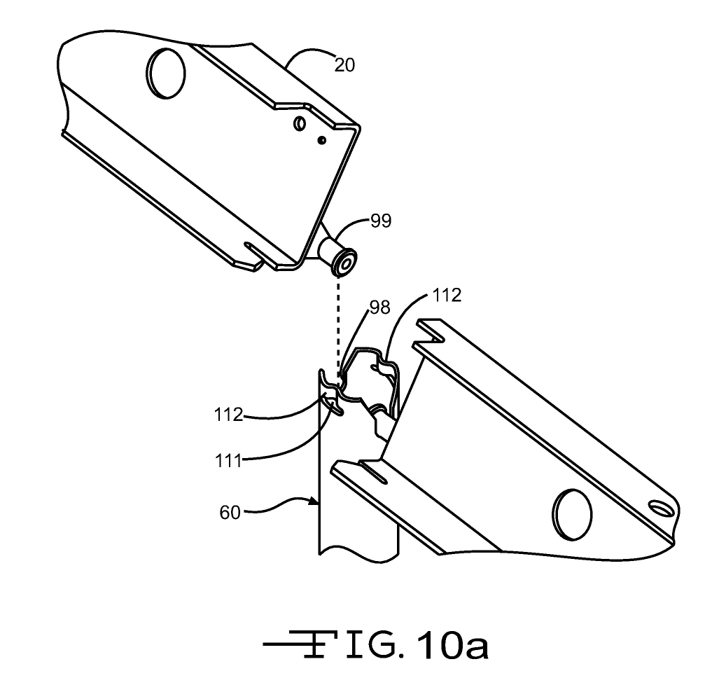

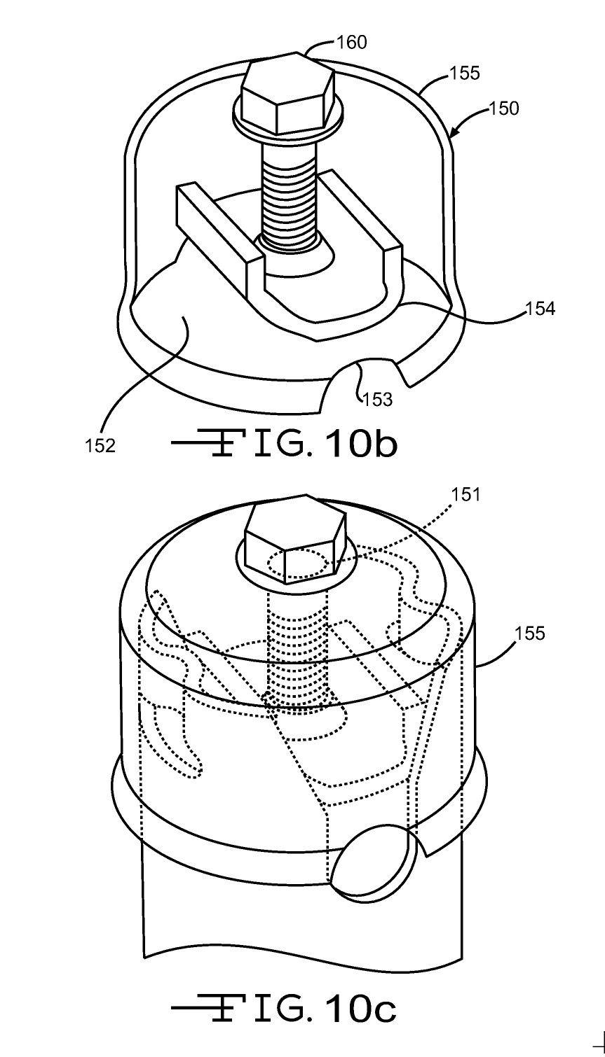

Referring to FIGS. 10a-c, the top end of the riser 60 has a pair of notches 98, circumferentially spaced 180 degrees apart, for cradling attachment lugs 99 carried by the frame members of cartridges 20. The lugs 99 may be attached to cartridge members by known means such as riveting, but preferably by mechanical staking. Riser 60 also has a pair of indentations or dimples 112 circumferentially spaced 90 degrees from each of the notches 98. The dimples 110 preferably are formed on site by the riser anchor assembly 120 as previously described. Slots 111 below each dimple 112 facilitate fabrication of the dimples. In a solar field, risers 60 are positioned in a row such that the notches 98 are aligned to allow next adjacent cartridges to share a common riser 60.

After the lugs 99 of next adjacent solar panel cartridges are positioned in a riser notch 98, a stamped metal bell-shaped cinch cap 120 is placed over the top of the riser 60. The cap 150 has a bolt hole 151. The cap 150 includes a pair of notches 153 corresponding to the riser notches 98. The cap 150 includes an internal wing bracket 154. To assemble, the bolt 130 is extended through the cap hole 151 and threaded onto the wing bracket 154. The cap 150 is then placed on a positioned riser 60 and the bolt 130 is turned, thereby rotating the ends of the wing bracket 124 into engagement with the riser dimples 112. This restricts further turning of the bracket 124. As the bolt is tightened further, the bracket 124 will be pulled upwardly against the dimples 112, causing the cap 150 to tighten down until the notch 153 engages the lugs 99 and locks the cap 150 in place.

The descriptions of specific embodiments of the invention herein is intended to be illustrative and not restrictive. The invention may be practiced otherwise than as specifically explained and illustrated without departing from its spirit or scope as defined by the appended claims.

What is claimed is:

1. A method of constructing a solar energy collection area, the area including a plurality of solar panels, the method comprising the steps of:
a. positioning a first plurality of risers for supporting a first solar panel cartridge,
b. positioning a second plurality of risers for supporting a second solar panel cartridge,
c. mounting the first solar panel cartridge onto the first plurality of risers after the second plurality of risers is positioned.

2. The method of claim 1 further comprising the step of mounting the second solar panel cartridge onto the second plurality of risers.

3. The method of claim 2 wherein each of the first and second solar panel cartridges includes at least one solar panel, the method further comprising the step of electrically connecting the solar panels.

4. The method of claim 3 wherein at least one of the cartridges is comprised of a plurality solar panels, and wherein the method further comprises the step of electrically connecting the solar panels of the at least one cartridge to each other prior to mounting the at least one cartridge onto the risers.

5. The method of claim 2 wherein at least one of the first and second cartridges is mounted onto at least one of the first plurality of risers and onto at least one of the second plurality of risers.

6. The method of claim 1 wherein the first pluralities of risers are positioned in a first linear array and the second plurality of risers are positioned in a second linear array parallel to the first linear array.

7. The method of claim 6 further comprising the step of positioning a third plurality of risers in a third linear array parallel to the first and second linear arrays.

8. A method for construction a solar energy collection site, the method comprising:
a. forming a solar panel cartridge,
b. mounting a plurality of solar panels onto the solar panel cartridge, and
c. delivering the solar panel cartridge to a solar collection site for mounting on a solar panel support.

9. The method of claim 8 further comprising the step of wiring the plurality of solar panels together prior to delivering the solar panel cartridge.

10. The method of claim 9 further comprising the step of securing the solar panel wires to the cartridge prior to delivering the solar panel cartridge.

11. The method of claim 8 further comprising the step of palletizing a plurality of solar panel cartridges prior to delivering the solar panel cartridge.

12. The method of claim 10 further comprising the step of palletizing a plurality of solar panel cartridges prior to delivering the solar panel cartridge.

13. A device for positioning solar panel support risers comprising:
a frame configured for attachment to a vehicle,
a drive for forcing a riser into the ground,
a drive for orienting the device, whereby the riser can be positioned in a predetermined orientation.

14. The device of claim 13 further including a drive for rotating a riser as it is being positioned in the ground.

15. The device of claim 13 wherein the device may be rotated about three axes by the drive for orienting the device.

16. The device of claim 13 further including a gyroscope for providing data for the drive for orienting the device.

17. The device of claim 13 wherein the frame comprises a frame component for attaching the device to a vehicle, wherein the drive for orienting the device is configured to orient the device relative to the vehicle.
